(19) United States
(12) Patent Application Publication
(10) Pub. No.: US 2026/0050725 A1
(43) Pub. Date: Feb. 19, 2026

(54) Unified Partial Reconfiguration (PR) Region for Programmable Logic Device

(71) Applicant: Altera Corporation, San Jose, CA (US)

(72) Inventors: Syama Sundara Reddy Eswaravaka, San Jose, CA (US); Shailendra Srivastava, Mountain View, CA (US); Srinivas Beeravolu, Los Gatos, CA (US)

(21) Appl. No.: 19/342,088

(22) Filed: Sep. 26, 2025

(51) Int. Cl. G06F 30/343

(52) U.S. Cl. CPC G06F 30/343

(57) ABSTRACT

Systems and methods for determining a partial reconfiguration region and/or boundary ports into or out of the partial reconfiguration region are provided. A system may include a programmable logic device and a data processing system. The programmable logic device may be configurable to be programmed with a plurality of partial reconfiguration personas in a partial reconfiguration region of the programmable logic device. The data processing system may determine a boundary of the partial reconfiguration region based on a superimposition of the plurality of partial reconfiguration personas.

### BACKGROUND

This disclosure relates to systems and methods to generate a system design with multiple personas in a unified partial reconfiguration (PR) region for a programmable logic device, such as a field programmable gate array (FPGA).

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it may be understood that these statements are to be read in this light, and not as admissions of prior art.

Integrated circuits are found in numerous electronic devices and provide a variety of functionality. Many integrated circuits include programmable logic circuitry that may be configured with a hardware system design to implement specific hardware designs. Partial reconfiguration (PR) allows users to dynamically modify a portion of programmable logic circuitry of a programmable logic device without modifying the rest. This flexibility enables the use of multiple “personas” of configurations on the same hardware, allowing different tasks to run at different times. Each persona may be restricted to using the same boundary ports into and out of the PR region, but the logic design for each persona could be completely different.

One major challenge in partial reconfiguration lies in designing the PR personas. A designer may design the PR personas to be programmed into a PR region that fits all the PR personas. The PR region encompasses all resources that are used by all of the PR personas, including programmable logic circuits and hardened logic circuits such as digital signal processors (DSPs) and memory blocks, to accommodate all of the PR personas. Additionally, a designer may carefully design the shape and location of boundary ports of the PR region to meet timing and other physical constraints. Designers often manually choose the PR region as they design the various PR personas. Designers in real-world scenarios often rely on an empty persona or the largest persona and intuition to iteratively define and refine the PR region, leading to a time-consuming, less predictable and suboptimal manual process. In addition to taking considerable time and resources to develop the PR region and PR personas, the PR region may take up significantly more die area than would be used by any single PR persona.

### BRIEF DESCRIPTION OF THE DRAWINGS

Various aspects of this disclosure may be better understood upon reading the following detailed description and upon reference to the drawings in which:

FIG. 1 is a block diagram of a system used to program a system design having multiple partial reconfiguration (PR) personas onto an integrated circuit device;

FIG. 2 is a block diagram of an example of the integrated circuit device that may be programmed with the system design;

FIG. 3 is a flow diagram of the integrated circuit device programmed with different personas over time;

FIG. 4 is a flowchart of a method for efficiently generating a set of PR personas in a PR region;

FIG. 5 is a flowchart of a method for defining a PR region based on constraints of the PR personas that will be programmed into the PR region;

FIG. 6 is a schematic diagram of various components of different PR personas when the PR personas are compiled;

FIG. 7 is a schematic diagram illustrating “hotspots” where the components of different PR personas are concentrated;

FIG. 8 is a schematic diagram showing the overlay of the hotspots of the different PR personas;

FIG. 9 is a schematic diagram of a PR region that would encompass the hotspots and hardened components of all of the PR personas;

FIG. 10 is a flowchart of a method for using iterative geometric overlay to select the PR region;

FIG. 11 is a flowchart of a method for determining unified input boundary port(s) of the selected PR region;

FIG. 12 is a schematic diagram illustrating the compilation of each PR persona revision with different default input boundary port placements along the PR region;

FIG. 13 is a schematic diagram illustrating a superimposition of each PR persona revision with the different default input boundary port placements along the PR region;

FIG. 14 is a schematic diagram illustrating the creation of unified virtual driver(s) that could drive all of the loads of the PR personas;

FIG. 15 is a schematic diagram illustrating identifying placement(s) of the unified virtual driver(s);

FIG. 16 is a schematic diagram illustrating recompiling each PR persona revision using the placement of the unified virtual driver(s) as the input boundary port(s);

FIG. 17 is a flowchart of a method for determining unified output boundary port(s) of the selected PR region;

FIG. 18 is a flowchart of a method for unified pin placement for multiple PR personas; and

FIG. 19 is a block diagram of a data processing system that may incorporate the systems and methods of this disclosure.

### DETAILED DESCRIPTION OF SPECIFIC EMBODIMENTS

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the phrase A “based on” B is intended to mean that A is at least partially based on B. Moreover, the term “or” is intended to be inclusive (e.g., logical OR) and not exclusive (e.g., logical XOR). In other words, the phrase A “or” B is intended to mean A, B, or both A and B.

Partial reconfiguration (PR) allows designers to dynamically modify a portion of programmable logic circuitry of a programmable logic device without modifying the rest. This provides significant flexibility. Multiple “personas” (e.g., different configurations) may be programmed at different times on the same hardware. This disclosure relates to systems and methods to efficiently generate partial reconfiguration (PR) personas on an integrated circuit device having programmable logic circuitry, such as a field programmable gate array (FPGA). Rather than involve human guessing and intuition, the systems and methods of this disclosure may enable designers to rapidly determine an area-efficient PR region with a set of unified boundary ports that accommodates all of the PR personas that will be used in partial reconfiguration during runtime.

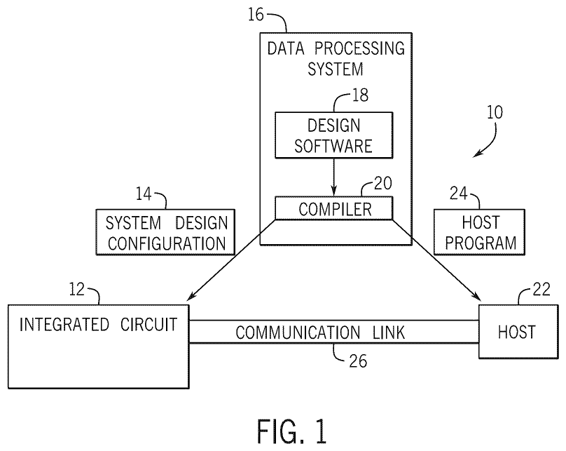

FIG. 1 illustrates a block diagram of a system 10 that may be used to program an integrated circuit device 12, such as an FPGA (e.g., Agilex™, Stratix®, Arria®, MAX®, or Cyclone® devices by Altera® Corporation), with such a system design using a system design configuration 14. Note that, while this disclosure largely refers to the integrated circuit device 12 as being a programmable logic device, such as an FPGA, in some embodiments, the integrated circuit device 12 may also include a one-time programmable device or structured application specific integrated circuit (ASIC), such as an Intel® eASIC™ device by Intel® Corporation. In other examples, the integrated circuit device 12 may be any suitable integrated circuit that is manufactured to have a particular system design with circuitry to perform desired data processing operations. The integrated circuit device 12 may be a single monolithic integrated circuit or a multi-die system of integrated circuits. The integrated circuit device 12 may include a single integrated circuit, multiple integrated circuits in a package, or multiple integrated circuits in multiple packages communicating remotely (e.g., via wires or traces) and may be referred to as an integrated circuit device or an integrated circuit system whether formed from a single integrated circuit or multiple integrated circuits in a package.

A designer may desire to implement the system design 14 (sometimes referred to as a circuit design or configuration) to perform a wide variety of possible operations on the integrated circuit device 12. In some cases, the designer may specify a high-level program to be implemented, such as an OPENCL® program that may enable the designer to more efficiently and easily provide programming instructions to configure a set of programmable logic cells for the integrated circuit device 12 without specific knowledge of low-level hardware description languages (e.g., Verilog, very high-speed integrated circuit hardware description language (VHDL)). For example, since OPENCL® is quite similar to other high-level programming languages, such as C++, designers of programmable logic familiar with such programming languages may have a reduced learning curve than designers that are required to learn unfamiliar low-level hardware description languages to implement new functionalities in the integrated circuit device 12.

In a configuration mode of the integrated circuit device 12, a designer may use a data processing system 16 (e.g., a computer including a data processing system having a processor and memory or storage) to implement high-level designs (e.g., a system user design) using design software 18 (e.g., executable instructions stored in a tangible, non-transitory, computer-readable medium such as the memory or storage of the data processing system 16), such as a version of Altera® Quartus® by Altera Corporation. The data processing system 16 may use the design software 18 and a compiler 20 to convert the high-level program into a lower-level description (e.g., a configuration program, a bitstream) as the system design configuration 14. The compiler 20 may provide machine-readable instructions representative of the high-level program to a host 22 and the system design configuration 14 to the integrated circuit device 12.

Additionally or alternatively, the host 22 running the host program 24 may control or implement the system design configuration 14 onto the integrated circuit device 12. For example, the host 22 may communicate instructions from the host program 24 to the integrated circuit device 12 via a communications link 26 that may include, for example, direct memory access (DMA) communications or peripheral component interconnect express (PCIe) communications. The designer may use the design software 18 to generate and/or to specify a low-level program, using low-level tools such as the low-level hardware description languages described above. Further, in some embodiments, the system 10 may be implemented without a separate host 22 or host program 24. Thus, embodiments described herein are intended to be illustrative and not limiting.

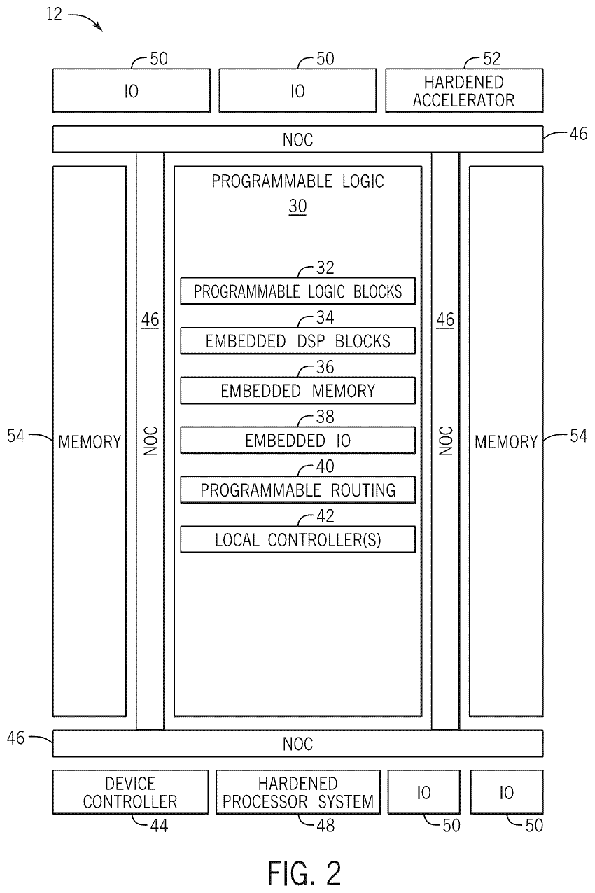

The integrated circuit device 12 may take any suitable form that may implement the system design configuration 14. In one example shown in FIG. 2, the integrated circuit device 12 may include programmable logic circuitry 30, which include a two-dimensional array of many different functional blocks, such as programmable logic blocks 32, embedded digital signal processing (DSP) blocks 34, embedded memory blocks 36, and embedded input-output blocks 38. In many cases, there may be rows or columns of these functional blocks that may be programmably connected to one another using programmable routing 40.

The programmable logic blocks 32 may be programmed to implement a wide variety of logic circuitry. The programmable logic blocks 32 may include a number of adaptive logic modules (ALMs), which may take the form of lookup tables (LUTs) that can be programmed to implement a logic truth table, effectively enabling any the programmable logic blocks 32 to implement any desired logic circuitry when configured with the system design configuration 14. The programmable logic blocks 32 and are sometimes referred to as logic array blocks (LABs) or configurable logic blocks (CLBs).

The embedded DSP blocks 34, embedded memory blocks 36, and embedded IO blocks 38 may be distributed around the programmable logic blocks 32. For example, there may be several columns of programmable logic blocks 32 for every column of DSP blocks 34, column of embedded memory blocks 36, or column of embedded IO blocks 38. The embedded DSP blocks 34 may include “hardened” circuits that are specialized to efficiently perform certain arithmetic operations. This is in contrast to “soft logic” circuits that may be programmed into the programmable logic blocks 32 to perform the same functions, but which may not be as efficient as the hardened circuits of the DSP blocks 34. The embedded memory blocks 36 may include dedicated local memory (e.g., blocks of 20 kB, blocks of 1 MB). The embedded IO blocks 38 may allow for inter-die or inter-package communication. The embedded DSP blocks 34, embedded memory blocks 36, and embedded IO blocks 38 may be accessible to the programmable logic blocks 32 using the programmable routing 40.

The various functional blocks of the programmable logic circuitry 30 may be grouped into programmable regions, sometimes referred to as logic sectors, that may be individually managed and configured by corresponding local controllers 42 (e.g., sometimes referred to as Local Sector Managers (LSMs)). The grouping of the programmable logic circuitry 30 resources on the integrated circuit device 12 into logic sectors, logic array blocks, logic elements, or adaptive logic modules is merely illustrative. In general, the integrated circuit device 12 may include functional logic blocks of any suitable size and type, which may be organized in accordance with any suitable logic resource hierarchy. Indeed, there may be other functional blocks (e.g., other embedded application specific integrated circuit (ASIC) blocks) than those shown in FIG. 2.

Before continuing, it may be noted that the programmable logic circuitry 30 of the integrated circuit device 12 may be controlled by programmable memory elements sometimes referred to as configuration random access memory (CRAM). Memory elements may be loaded with configuration data (also called programming data or a configuration bitstream) that represents the system design configuration 14. Once loaded, the memory elements may provide a corresponding static control signal that controls the operation of an associated functional block. In one scenario, the outputs of the loaded memory elements are applied to the gates of metal-oxide-semiconductor transistors in a functional block to turn certain transistors on or off and thereby configure the logic in the functional block including the routing paths. Programmable logic circuit elements that may be controlled in this way include parts of multiplexers (e.g., multiplexers used for forming routing paths in interconnect circuits), look-up tables, logic arrays, AND, OR, NAND, and NOR logic gates, pass gates, and the like. The configuration memory elements may use any suitable volatile and/or non-volatile memory structures such as random-access-memory (RAM) cells, fuses, antifuses, programmable read-only-memory (ROM) memory cells, mask-programmed, laser-programmed structures, or combinations of structures such as these.

A device controller 44, sometimes referred to as a secure device manager (SDM), may manage the operation of the integrated circuit device 12. The device controller 44 may include any suitable logic circuitry to control and/or program the programmable logic circuitry 30 or other elements of the integrated circuit device 12. For example, the device controller 44 may include a processor (e.g., an x86 processor or a reduced instruction set computer (RISC) processor, such as an Advanced RISC Machine (ARM) processor or a RISC-V processor) that executes instructions stored on any suitable tangible, non-transitory, machine-readable media (e.g., memory or storage). Additionally or alternatively, the device controller 44 may include a hardware finite state machine (FSM). The device controller 44 may provide other functions, such as serving as a platform for virtual machines that may manage the operation of the integrated circuit device 12.

A network-on-chip (NOC) 46 may connect the various elements of the integrated circuit device 12. The NOC 46 may provide rapid, packetized communication to and from the programmable logic circuitry 30 and other blocks, such as a hardened processor system 48, high-speed input-output (IO) blocks 50, a hardened accelerator 52, and local device memory 54. The integrated circuit device 12 may include the hardened processor system 48 when the integrated circuit device 12 takes the form of a system-on-chip (SOC). The hardened processor system 48 may include a hardened processor (e.g., an x86 processor or a reduced instruction set computer (RISC) processor, such as an Advanced RISC Machine (ARM) processor or a RISC-V processor) that may act as a host machine on the integrated circuit device 12. The high-speed IO blocks 50 may enable communication using any suitable communication protocol(s) with other devices outside of the integrated circuit device 12, such as a separate memory device. The hardened accelerator 52 may include any hardened application-specific integrated circuitry (ASIC) logic to perform a desired acceleration function. For example, the hardened accelerator 52 may include hardened circuitry to perform cryptographic or media encoding or decoding. The memory 54 may provide local device memory (e.g., cache) that may be readily accessible by the programmable logic circuitry 30.

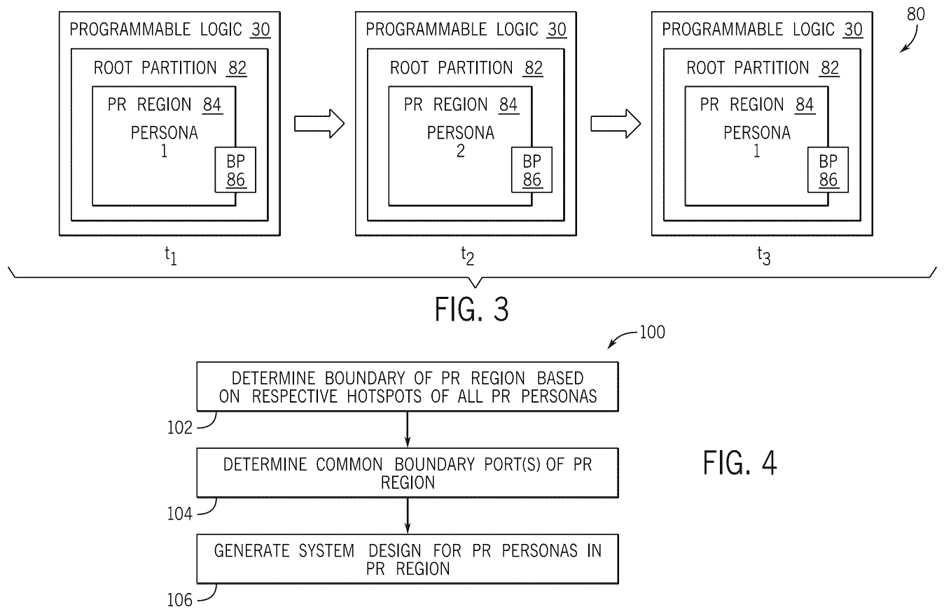

The integrated circuit device 12 may be used to implement a number of different partial reconfiguration (PR) personas during runtime. FIG. 3 illustrates an example of a runtime sequence 80 in which the programmable logic 30 is programmed to run different PR personas at different times t1, t2, and t3. The programmable logic circuitry 30 has a static region referred to as a root partition 82 that encapsulates a PR region 84. Input and output boundary ports 86 connect the root partition 82 with PR region 84. At various times (e.g., as controlled by the host 22 of FIG. 1 or the device controller 44 or hardened system processor 48 of FIG. 2), the PR region 84 is reprogrammed with a different PR persona. At time t1, the PR region 84 is programmed with a first PR persona (PERSONA 1); at time t2, the PR region 84 is programmed with a second PR persona (PERSONA 2); and at time t3, the PR region 84 is once again programmed with the PR first persona (PERSONA 1). The root partition 82 provides a framework to support the PR personas that are programmed into the PR region 84, and thus the root partition 82 may remain static while the PR region 84 is reprogrammed with different PR personas.

FIG. 4 illustrates a flowchart 100 of a method for implementing an area-efficient system design for a set of PR personas on an integrated circuit device. As will be described in greater detail below, the method includes using the design software 18 and/or the compiler 20 to initially determine a boundary for the PR region 84 that covers the hotspots and hardened circuits (e.g., embedded digital signal processing (DSP) blocks 34, embedded memory blocks 36, and embedded input-output blocks 38) used by the set of PR personas (process 102). The design software 18 and/or the compiler 20 may subsequently determine unified (e.g., universal, common to all PR personas) input and output boundary port(s) for the PR region 84 (process 104). Having determined the boundary and the boundary ports for the PR region 84, the design software 18 and/or the compiler 20 may generate the system design configuration 14 with for area-efficient partial reconfiguration (process 106).

### Determining the Boundary of a PR Region

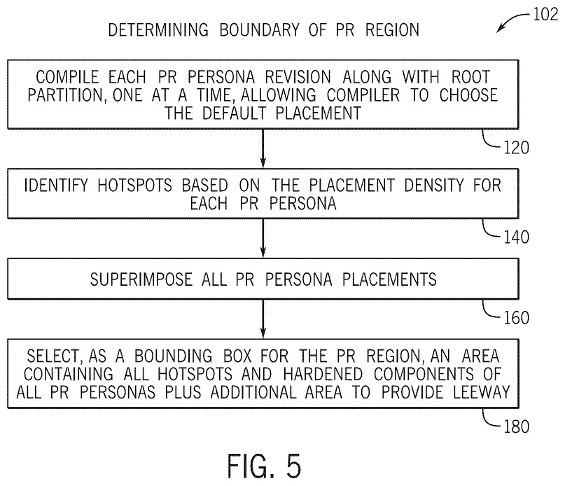

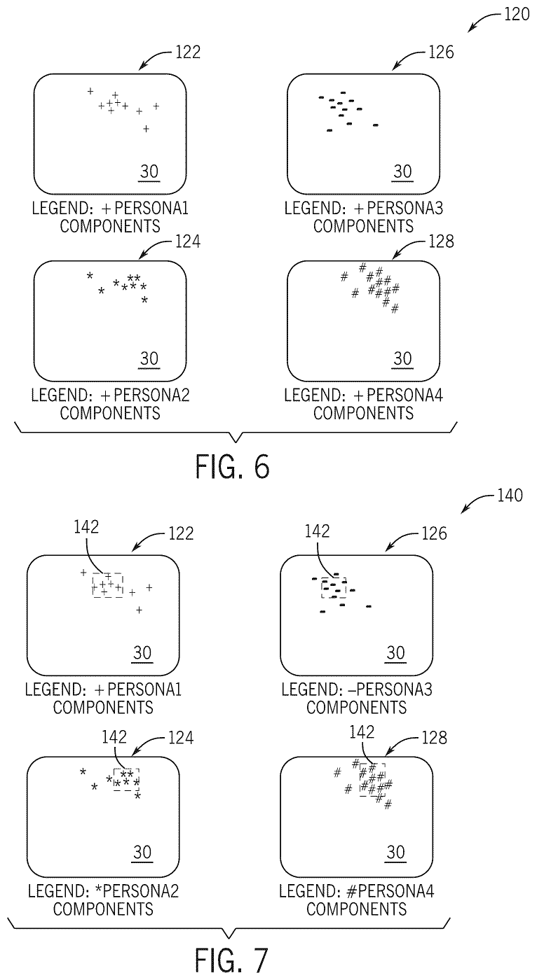

FIGS. 5-9 relate to determining a boundary of a PR region 84 in a manner consistent with the process 102 of FIG. 4. In particular, FIG. 5 is a flowchart corresponding to the process block 102 and FIGS. 6-9 provide examples of the various actions of the flowchart of FIG. 5. As such, FIGS. 6-9 will be discussed concurrently with FIG. 5. The flowchart of FIG. 5 may be carried out using any suitable data processing system, such as the data processing system 16 of FIG. 1. The design software 16 and/or the compiler 18 may determine the boundary of the PR region 84 to support a set of PR personas.

The flowchart of FIG. 5 begins with compiling each PR persona revision, along with the root partition, one at a time (process 120). The design software 16 and/or the compiler 18 may choose a default placement based on any suitable constraints. FIG. 6 provides one visual example of the process 120 for four different PR persona revisions shown as persona1, persona2, persona3, and persona4. The default placement of various components of the four different PR persona revisions into the programmable logic circuitry 30 are shown in compilations 122, 124, 126, and 128, respectively. In some cases, the region of programmable logic circuitry 30 for compilation of the various PR personas may be constrained to a particular region than the entirety of the programmable logic circuitry 30 available, but this initial region is still likely to be much larger than the ultimately selected PR region 84. Note that each PR persona may be marked as a cluster (e.g., user doesn't enforce logic lock on it), so the placer/fitter tool of the design software 16 and/or the compiler 18 may strives to place the logic of the PR personas together (e.g., as compact as possible). This achieves a legal placement for each PR persona independently using the design software 16 and/or the compiler 18.

Returning to the flowchart of FIG. 5, having compiled the various PR personas, the design software 16 and/or the compiler 18 may identify “hotspots” based on the placement density for each PR persona revision that has been compiled (process 140). FIG. 7 illustrates that, in the process 140, hotspot regions 142 of the programmable logic circuitry 30 may be defined where the densest parts of the compilations 122, 124, 126, and 128 appear. A density threshold to define what is considered a hotspot may be empirically decided for a target device family or a target use case. For example, a device with more programmable logic circuitry 30 area may define a hotspot as a region of lower density. The density threshold may be an amount of density of programmable logic circuitry 30 that is used by a PR persona in relation to a total amount of programmable logic circuitry 30 or an amount of density of programmable logic circuitry 30 that is used by a PR persona in relation to the entirety of the area used by the PR persona. For example, a hotspot region 142 may be identified as such when the density of the programmable logic circuitry 30 that is used by a PR persona exceeds 10%, 20%, 30%, 40%, 50%, 60%, 70%, 80%, 90%, or the like. Moreover, there may be multiple hotspot regions 142 for each PR persona; the example of FIG. 7 shows one hotspot region 142 per PR persona for ease of explanation.

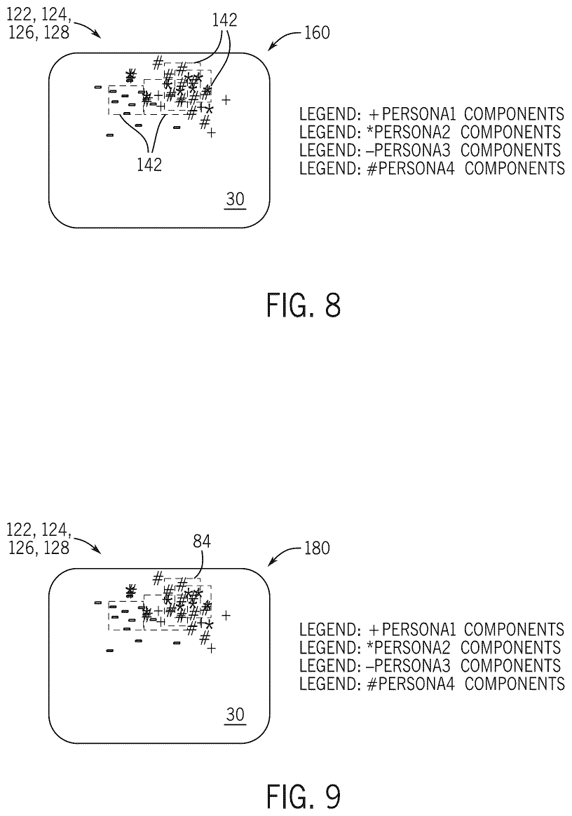

Following the process 140 in the flowchart of FIG. 5, the design software 16 and/or the compiler 18 may superimpose the PR persona compilations (process 160). An illustration of the process 160 is shown in FIG. 8. The design software 16 and/or the compiler 18 may superimpose the PR persona compilations 122, 124, 126, and 128, along with their identified hotspot regions 142 in the programmable logic circuitry 30.

Following the process 160 in the flowchart of FIG. 5, the design software 16 and/or the compiler 18 may select the boundary of the PR region 84 based on the superimposed persona compilations (process 180). For example, the design software 16 and/or the compiler 18 may select, as a bounding box for the PR region 84, an area that at least partially contains all of the hotspot regions 142 and any hardened components (e.g., embedded digital signal processing (DSP) blocks 34, embedded memory blocks 36, and embedded input-output blocks 38) that are used by any of the PR personas in the programmable logic circuitry 30.

FIG. 9 provides a visual example of the process 180. As shown in FIG. 9, the PR persona compilations 122, 124, 126, and 128 in the programmable logic circuitry 30 are superimposed. A PR region 84 has been selected that at least partially contains all of the hotspot regions 142 and any hardened components that are used by any of the PR persona compilations 122, 124, 126, and 128. The design software 16 and/or the compiler 18 may use a convex hull-based algorithm (e.g., modified convex hull algorithm) to determine a suitable rectilinear shape unifying the hotspot regions 142. The algorithm may take into account the density of the placement of the superimposed (e.g., unified) set of PR persona compilations 122, 124, 126, and 128 so the design software 16 and/or the compiler 18 can generate multiple sub-hulls and at the end combine the sub-hulls to come up with a final rectilinear hull.

While optimizing the shape (e.g., selecting an efficient shape) for the PR region 84, the convex hull algorithm used by the design software 16 and/or the compiler 18 may also consider the maximum resource requirement by type to be used by any of the PR persona compilations. For example, if persona1 uses 10 DSP blocks, pesona2 uses 2 DSP blocks, persona3 uses 5 DSP blocks, and persona4 uses 7 DSP blocks, the inferred unified PR region 84 must be able to accommodate 10 DSP blocks, which is the most used by any single one of the PR personas. In addition, the convex hull algorithm used by the design software 16 and/or the compiler 28 may also consider any fixed placements (e.g., hardened blocks) in any of the PR persona compilations and lock them in the inferred unified PR region 84. The reason is that the hardened blocks are limited and have fixed placement. As such, the unified PR region 84 is selected to cover those hard blocks' placement locations.

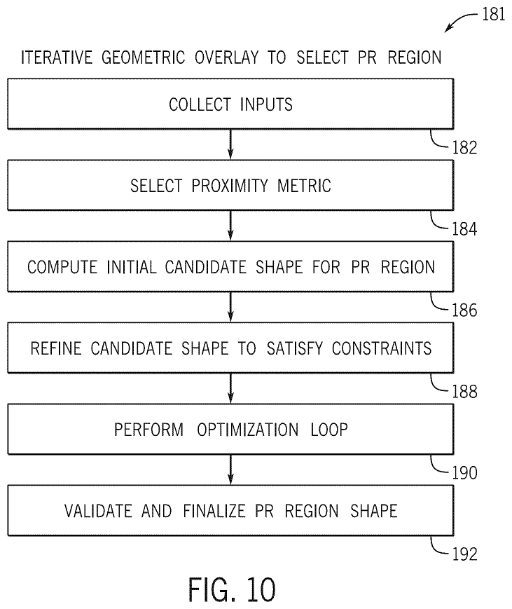

Another approach to determining the PR region 84, using iterative geometric overlay, is described by a flowchart 181 of FIG. 10. The flowchart 181 of FIG. 10 may be carried out using any suitable data processing system, such as the data processing system 16 of FIG. 1. The design software 16 and/or the compiler 18 may collect inputs including shapes corresponding to the placement of the PR persona compilations and constraints corresponding to each PR persona compilation (process 182). The design software 16 and/or the compiler 18 may establish a proximity metric defined as a distance measure or similarity metric to evaluate how close a candidate shape is to each preferred shape (process 184). Examples include an overlap area, bounding rectangle difference, Hausdorff distance, or the like.

Using these inputs and metric, the design software 16 and/or the compiler 18 may compute an initial candidate for the PR region 84 (process 186). For example, the design software 16 and/or the compiler 18 may determine to use a union or intersection. A union may be selected if the PR region 18 will encompass areas from any PR persona compilation. An intersection may be selected if the PR region 84 is to take a shape commonly shared by all PR persona compilations, though this is often too small or even empty. Additionally or alternatively, a weighted overlay may be obtained. If different shapes of the PR persona compilations have different priorities, weights w₁, w₂, . . . , wₙ may be applied to each shape and a weighted overlay (e.g., a geometric “average”) may be obtained. This yields an initial candidate shape, Cᵢₙᵢₜᵢₐₗ.

The design software 16 and/or the compiler 18 may refine the initial shape to satisfy constraints (process 188). The design software 16 and/or the compiler 18 may use optimization or heuristic methods to iteratively adjust Cᵢₙᵢₜᵢₐₗ (to other candidate shapes Cᵢ, where i is an integer that refers to the current iteration) to ensure the shape of the PR boundary meets the constraints of the PR personas. These may include resource feasibility, timing and physical constraints, and shape and/or geometry constraints.

For resource feasibility, the design software 16 and/or the compiler 18 may perform a resource feasibility check. The design software 16 and/or the compiler 18 may confirm that the candidate shape Cᵢ contains enough ALMs, DSPs, and hardened memory blocks for each PR persona. If the resources in the candidate shape Cᵢ are insufficient, the design software 16 and/or the compiler 18 may expand or shift the region to include more of the required resources.

To satisfy the timing and physical constraints, the design software 16 and/or the compiler 18 may check feasibility with respect to routing paths or timing-critical blocks. The design software 16 and/or the compiler 18 may adjust the boundary of the candidate shape Cᵢ to reduce timing violations (e.g., move edges closer to related logic blocks).

To satisfy the shape/geometry constraints, the design software 16 and/or the compiler 18 may enforce permissible shapes (e.g., rectangular bounding, contiguous areas) and respect any forbidden or obstructed regions of the programmable logic circuitry. For example, if there are any partitions that have been reserved for a particular purpose that does not permit placement of the PR personas, the candidate shape Cᵢ may be adjusted to avoid those areas while satisfying the other constraints.

The refined candidate shape Cᵢ may be reduced in size to consume less of the valuable area of the programmable logic circuitry 30. The design software 16 and/or the compiler 18 may reduce (e.g., optimize) the candidate shape Cᵢ using an optimization loop to satisfy constraints (process 190). For example, the design software 16 and/or the compiler 18 may define a cost function to balance proximity and constraint satisfaction of the candidate shape Cᵢ. The cost function may take any suitable form. One example of such a cost function is shown below:

$$Cost ( C ) = α \times ProximityCost ( C ) + β \times ResourceViolation ( C ) + γ \times TimingViolation ( C ) ,$$

where ProximityCost(C) is a function corresponding to how far the candidate shape Cᵢ is from each PR persona compilation placement (e.g., using overlap or geometric distance), ResourceViolation(C) is a function that penalizes if resource requirements are not fully met, TimingViolation(C) is a function that measures how many or how severe timing violations occur within the candidate shape Cᵢ. The variables α, β, and γ represent coefficients applying a particular weight to each constraint.

The design software 16 and/or the compiler 18 may perform an iterative search based on the selected cost function using any suitable search algorithm. For example, the design software 16 and/or the compiler 18 may use simulated annealing, genetic algorithms, or tabu search. In general, the design software 16 and/or the compiler 18 may start with the initial candidate shape Cᵢₙᵢₜᵢₐₗ. At each iteration, the design software 16 and/or the compiler 18 may propose a small modification, such as expanding or shrinking an edge, shifting part of the candidate shape Cᵢ to capture more resources, or reorient the candidate shape Cᵢ boundary to reduce routing distance. The design software 16 and/or the compiler 18 may accept or reject the changes based on whether the overall cost is improved or within an acceptable tolerance. Ultimately, design software 16 and/or the compiler 18 may terminate the search when the results converge (e.g., when changes no longer yield meaningful improvements) or after a set number of iterations and determine a final candidate region C_{final}.

Once a candidate shape Cᵢ has been selected, the design software 16 and/or the compiler 18 may validate and finalize the shape of the PR region (process 192). For example, the design software 16 and/or the compiler 18 may check that the final candidate region C_{final} meets all constraints for each partition, including resources (e.g., ALMs, DSPs, embedded memory), timing and routing path, physical feasibility (appearing in an allowed region on the programmable logic circuitry 30). The design software 16 and/or the compiler 18 may then output the final candidate region C_{final} as the PR region boundary.

Note that there are trade-offs—there are often compromises between staying close to each initial PR persona compilation shape and meeting design and resource constraints. This approach uses iterative refinement, where an initial overlay provides a good starting point, but constraints are enforced through iterative adjustments. These tools are also flexible. Using heuristic or meta-heuristic algorithms can effectively handle the complexity and multi-objective nature of the problem. This approach balances the diverse geometry and resource constraints while finding a common region that closely aligns with the initial PR persona compilation placement.

### Determining Unified Input and Output Boundary Ports of a PR Region

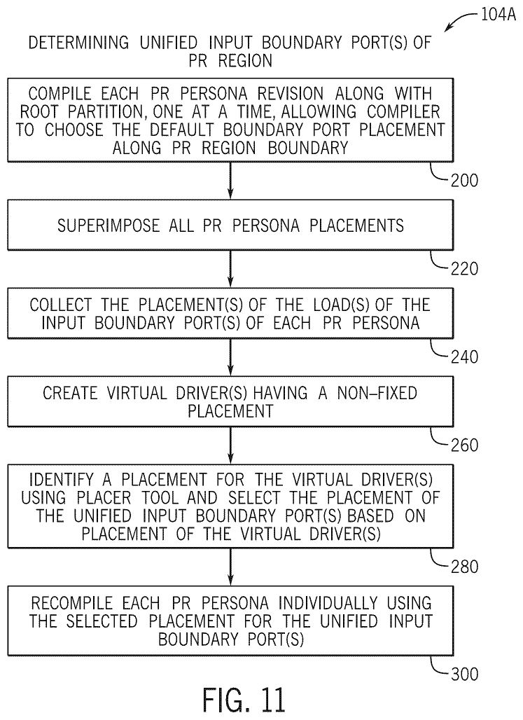

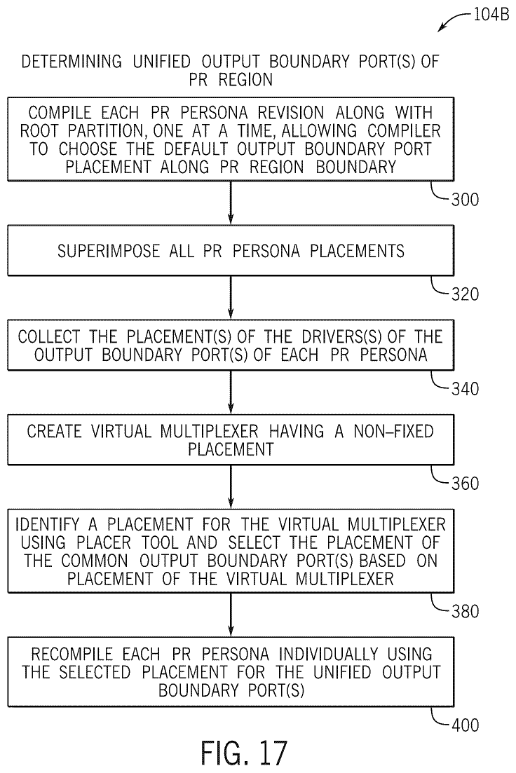

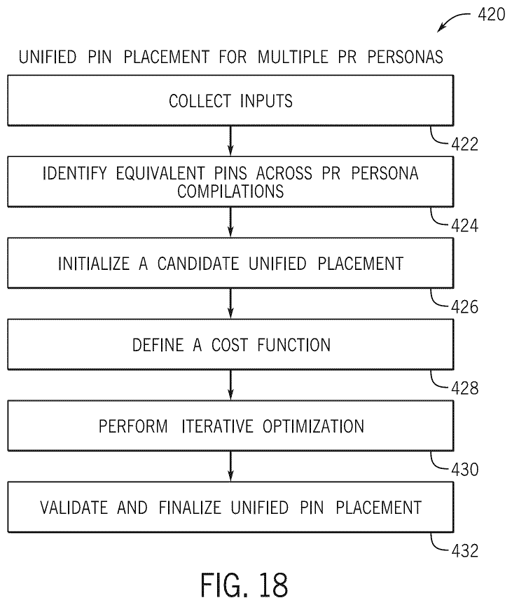

Regardless of the manner that the boundary of the PR region is determined, the various PR personas that will be configured during runtime will use the same input boundary ports and output boundary ports along the boundary of the PR region. These are sometimes referred to as input boundary pins and output boundary pins. FIGS. 11-16 relate to determining unified input boundary ports of a PR region, FIG. 17 is a flowchart of a method for determining unified output boundary ports of a PR region, and FIG. 18 is a flowchart of another method for determining unified input ports and output boundary ports of the PR region.

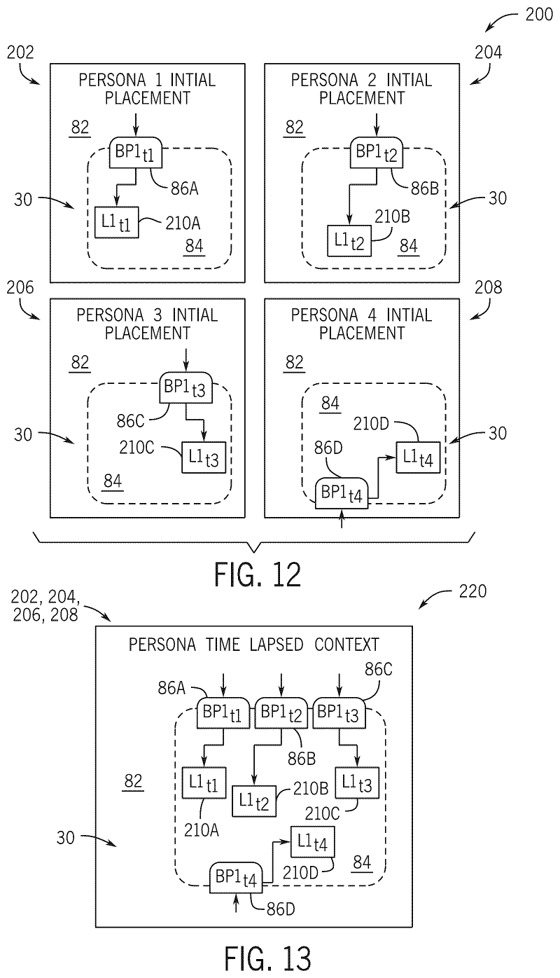

Turning to FIG. 11, a flowchart 104A represents a method for performing part of the process 104 previously described with reference to FIG. 4, namely, determining unified input boundary ports for a PR region. FIGS. 12-16 provide examples of the various actions of the flowchart 104A of FIG. 11. As such, FIGS. 12-16 will be discussed concurrently with FIG. 11. The flowchart 104A of FIG. 11 may be carried out using any suitable data processing system, such as the data processing system 16 of FIG. 1. The design software 16 and/or the compiler 18 may determine the input boundary ports of the PR region that has been previously determined (e.g., using the techniques discussed above) to support a set of PR personas.

The flowchart 104A of FIG. 11 begins with compiling each PR persona revision, along with the root partition, one at a time (process 200). The design software 16 and/or the compiler 18 may choose a default placement for input boundary ports along the boundary of the PR region based on any suitable constraints. FIG. 12 provides one visual example of the process 200 for the same four different PR persona revisions mentioned above, shown here as persona1, persona2, persona3, and persona4. The design software 16 and/or the compiler 18 may compile the four different PR persona revisions into the previously determined PR region 84, which is situated within the static root partition 82, of the programmable logic circuitry 30. These are shown as initial compilations 202, 204, 206, and 208, respectively. For each initial compilation 202, 204, 206, and 208, the design software 16 and/or the compiler 18 may perform an initial placement of an input boundary port 86, as well as a load 210 that receives data through the boundary port 86, according to any suitable placement technique. This results in different placements for the different compilations 202, 204, 206, and 208. The compilation 202 includes an input boundary port (BP1t1) 86A supplying data to a load (L1t1) 210A for persona1. The compilation 204 includes a boundary port (BP1t2) 86B supplying data to a load (L1t2) 210B for persona2. The compilation 206 includes a boundary port (BP1t3) 86C supplying data to a load (L1t3) 210C for persona3. The compilation 208 includes a boundary port (BP1t4) 86D supplying data to a load (L1t4) 210D for persona4.

While only one boundary port 86 and one load 210 are illustrated for each of the compilations 202, 204, 206, and 208 for ease of explanation, different PR personas may include many more input boundary ports 86. Moreover, some PR personas may use more input boundary ports 86 than other PR personas. Moreover, in some embodiments, the placement of the input boundary port(s) may be constrained to a particular section of the boundary of the PR region 84, whereas in other embodiments, the placement of the input boundary port(s) may be anywhere along the boundary of the PR region 84.

Following the process 200 in the flowchart 104A of FIG. 11, the design software 16 and/or the compiler 18 may superimpose the PR persona compilations (process 220). An illustration of the process 220 is shown in FIG. 13. The design software 16 and/or the compiler 18 may superimpose the PR persona compilations 202, 204, 206, and 208, preserving their positions within the PR region 84, which is situated within the root partition 82, in the programmable logic circuitry 30. The input boundary ports 86A, 86B, 86C, and 86D remain connected to their respective loads 210A, 210B, 210C, and 210D.

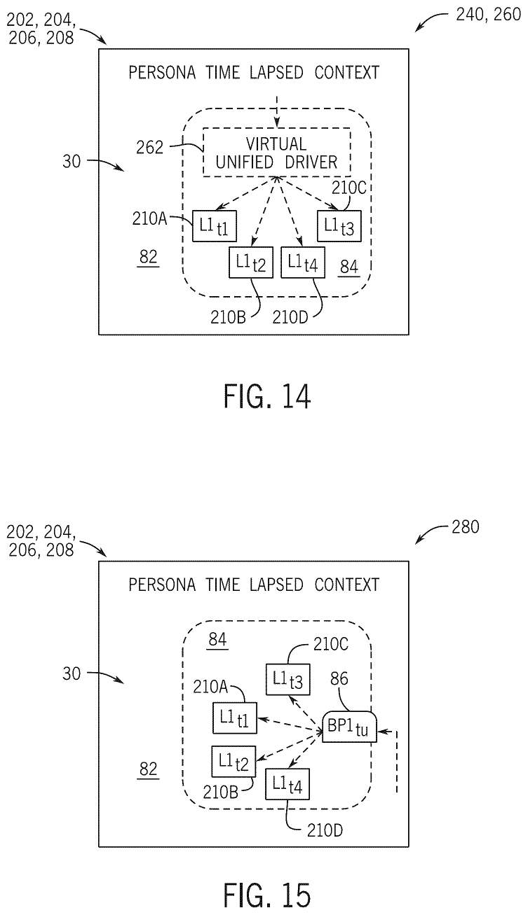

Returning to the flowchart 104A of FIG. 11, the design software 16 and/or the compiler 18 may collect the placements of the loads 210 for each PR persona (process 240). The design software 16 and/or the compiler 18 may model the loads 210 as well as the driver of its corresponding input boundary port 86 as loads that are driven by a virtual driver with a non-fixed placement (process 260). FIG. 14 provides an example of the processes 240 and 260. The boundary ports 86A, 86B, 86C, and 86D are modeled together in a time-lapsed context (superimposed) along with the respective loads 210A, 210B, 210C, and 210D as unified loads driven by a single virtual unified driver 262. The virtual unified driver 262 does not have a fixed placement. If there are multiple sets of boundary ports 86 (e.g., at least one of the PR personas uses two or more input boundary ports 86), there may be corresponding multiple virtual unified drivers 262.

As shown in FIG. 11, the design software 16 and/or the compiler 18 may use any suitable (e.g., default) technique to identify a placement for the unified virtual driver(s) 262 using its placer tool and select the placement of final unified input boundary port(s) 86 based on placement of the virtual driver(s) 262 (process 280). FIG. 15 provides an example of the process 280. The design software 16 and/or the compiler 18 may use any suitable placer algorithm/tool to identify a placement (e.g., an optimal placement) for the unified virtual driver 262. The problem is now reduced to a placement problem of the sort that the design software 16 and/or the compiler 18 excel at solving. The identified placement of the unified virtual driver 262 may be selected as a final placement for a unified input boundary port 86.

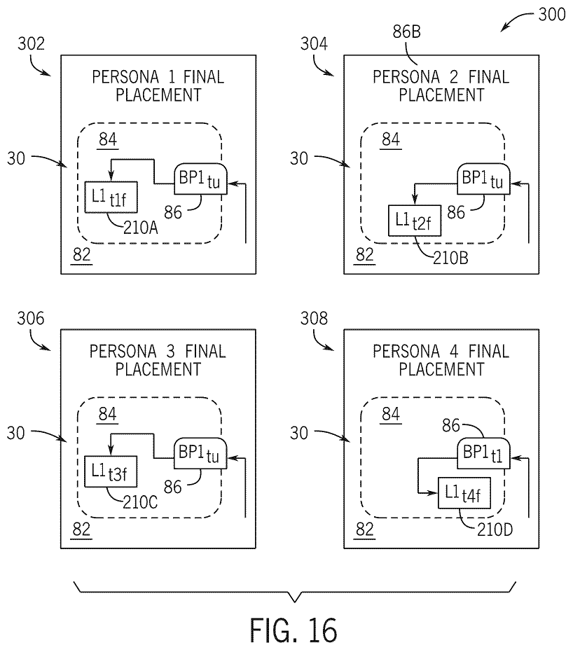

Having identified the final placement for the unified input boundary port 86, the design software 16 and/or the compiler 18 may recompile each PR persona individually using the selected input boundary port 86 (process 300 of FIG. 11). FIG. 16 provides an example of the process 300. The design software 16 and/or the compiler 18 may use any suitable placer algorithm to consider the unified input boundary port (BP1tu) 86 as an optimal placement for the input boundary port 86 and recompile each PR persona independently. The unified input boundary port (BP1tu) 86 placement may be locked or considered as a seed for the placer tool of the design software 16 and/or the compiler 18. It is a choice for the placer implementation. As a result, revised compilations 302, 304, 306, and 308 for persona1, persona2, persona3, and persona4, respectively, are generated in the PR region 84 connecting the loads 210A, 210B, 210C, and 210D, respectively, to the unified input boundary port 86. As a corollary, if there is at least one valid placement for a boundary port 86 that works for all the planned PR personas, then it is possible for the placer of the design software 16 and/or the compiler 18 to eventually find it when the placement constraints of all of the PR personas are solved together in one context. And then, the results (the unified placement of the boundary port 86) may be back annotated, and another pass of full compilation may be performed on each PR persona to finalize the placement and routing for improved (e.g., optimal) utilization and timing. Also note that the final placement generated in the process 300 for the internal logic of each PR persona may be different from their ‘initial placement’ in the process 200, but this is for good, with better packing and/or timing.

Whereas the flowchart 104A of FIG. 11 describes a manner of determining unified input boundary ports 86 of a PR region 84, FIG. 17 is a flowchart 104B describing a method for determining unified output boundary ports 86 of the PR region 84. Turning to FIG. 17, the flowchart 104B represents a method for performing another part of the process 104 previously described with reference to FIG. 4, namely, determining unified output boundary ports for a PR region. The flowchart 104B of FIG. 17 may be carried out using any suitable data processing system, such as the data processing system 16 of FIG. 1. The design software 16 and/or the compiler 18 may determine the output boundary ports of the PR region that has been previously determined (e.g., using the techniques discussed above) to support the set of PR personas.

The flowchart 104B of FIG. 17 begins with compiling each PR persona revision, along with the root partition, one at a time (process 300). The design software 16 and/or the compiler 18 may choose a default placement for output boundary ports along the boundary of the PR region based on any suitable constraints, while keeping the input boundary ports 86 as previously determined (e.g., according to the flowchart 104A of FIG. 11). The design software 16 and/or the compiler 18 may superimpose the PR persona compilations including various initial output boundary port placements and output drivers associated with the initial output boundary port placements (process 320). The design software 16 and/or the compiler 18 may collect the placements of the output drivers for each PR persona (process 340). The design software 16 and/or the compiler 18 may model the output drivers and their corresponding initial output boundary port locations through a unified virtual multiplexer with a non-fixed placement to loads in the root partition (process 360). The design software 16 and/or the compiler 18 may use any suitable (e.g., default) technique to identify a placement for the unified virtual multiplexer using its placer tool and select the placement of final unified output boundary port(s) based on the placement of the virtual multiplexer (process 380). Having identified the final placement for the unified output boundary port(s), the design software 16 and/or the compiler 18 may recompile each PR persona individually using the selected input boundary port and output boundary port (process 400).

A flowchart 420 of FIG. 18 provides another approach to determining the input and output boundary ports of the PR region (sometimes also referred to as “pins”). The flowchart 420 of FIG. 18 may be carried out using any suitable data processing system, such as the data processing system 16 of FIG. 1. The design software 16 and/or the compiler 18 may collect inputs including shapes S₁, S₂, . . . , Sₙ corresponding to the default (e.g., preferred) placement of the PR persona compilations, pin placements P₁, P₂, . . . , Pₙ corresponding to the default (e.g., preferred) placement of the input and output boundary ports (also sometimes referred to as “pins”), and constraints corresponding to each PR persona compilation (process 422). Each shape Sᵢ corresponds to the default (e.g., preferred) placement of the PR persona compilation i. Each pin Pᵢ corresponds to the default (e.g., preferred) placement of the input and output boundary ports (also sometimes referred to as “pins”) of the PR persona compilation i. This includes both the logical pin IDs (e.g., pin A, pin B) and coordinates within shape Sᵢ. The constraints may include resource constraints, timing and routing constraints, and physical constraints. The resource constraints include the availability of ALMs, DSPs, and hardened memory blocks for each PR persona. The timing and routing constraints include critical paths and maximum allowable wire length. The physical constraints include respecting (e.g., avoiding) any forbidden or reserved areas of the programmable logic circuitry or alignment to certain grid boundaries, to name a few.

The design software 16 and/or the compiler 18 may identify equivalent pins across PR persona compilations (process 424). Logical pin matching may entail determining which pins in different PR persona compilations correspond to the same logical signals (e.g., “Pin A” in Persona 1 is also “Pin A” in Persona 2). These logically equivalent pins may be grouped into sets (e.g., Group(A)={P_{1,A},P_{2,A}, . . . , P_{k,A}.

Using the pin groups that have been identified, the design software 16 and/or the compiler 18 may initialize a candidate unified pin placement (process 426). For example, for each pin group, the design software 16 and/or the compiler 18 may compute an initial “average” or centroid position across all PR personas' placements. This gives a first-pass estimate for each pin's unified location. If there is already a common PR region shape determined (or if it is being derived in parallel), these centroid placements may be ensured to fall within the PR region or the pin placement may be adjusted to move to the PR region boundary.

The design software 16 and/or the compiler 18 may identify how well a candidate unified pin placement (for all pins) satisfies the constraints of each PR persona by defining a cost function (process 428). The cost function may take any suitable form. One example of such a cost function is shown below:

$$( {P}_{unified} ) = α \times {\sum }_{A} ( ProximityCost ( A ) ) + β \times TimingViolation ( Punified ) + γ \times ResourceViolation ( Punified ) + δ \times PlacementRulePenalty ( Punified )$$

where ProximityCost(A) is a function corresponding to how far the unified location of pin A is from each PR persona's default (e.g., initial position, preferred position) (e.g., using overlap or geometric distance), ResourceViolation(Punified) is a function that penalizes if resource requirements are not fully met (e.g., configurations that exceed available ALMs, DSPs, and hardened memory blocks in the final PR region layout), Timing Violation(Punified) is a function that quantifies any increase in routing delays or critical path violations caused by pin locations, and PlacementRulePenalty(Punified) is a function that accounts for design rules (e.g., pins are to be placed on boundaries or avoid restricted columns). The variables α, β, γ, and δ represent coefficients applying a particular weight to each constraint.

The design software 16 and/or the compiler 18 may perform iterative refinement based on the cost function using any suitable search algorithm (process 430). For example, the design software 16 and/or the compiler 18 may use simulated annealing, genetic algorithms, or tabu search. For example, the design software 16 and/or the compiler 18 may start with the centroid-based placement for each pin. The design software 16 and/or the compiler 18 may propose small “moves” for pin locations, such as shifting individual pins up/down/left/right within the allowable region. Group moves may be considered if certain pins are constrained to stay near each other (within some fixed distance or logical region) due to logical or routing constraints. The design software 16 and/or the compiler 18 may accept or reject moves. For example, the design software 16 and/or the compiler 18 may calculate a new cost with the proposed change using the cost function. If the cost is lower (or meets acceptance criteria in the case of simulated annealing), the design software 16 and/or the compiler 18 may adopt the change. Otherwise, the design software 16 and/or the compiler 18 may revert or keep searching. The design software 16 and/or the compiler 18 may terminate the search when improvements become negligible (e.g., fall within a low threshold level of area efficiency) or a maximum iteration count is reached. This may be selected as the final Punified set of pin positions.

Using the Punified set of pin positions, the design software 16 and/or the compiler 18 may validate and finalize this final pin placement (process 432). The design software 16 and/or the compiler 18 may check that each PR persona can still operate using the unified pin locations. For example, the design software 16 and/or the compiler 18 may verify whether all persona-specific resource needs are met with this placement and whether routing and timing still meet design specifications. The design software 16 and/or the compiler 18 may further verify that no physical or design rule is violated (e.g., boundary alignment, spacing from restricted areas). The design software 16 and/or the compiler 18 may also document any trade-offs (e.g., slight increases in routing complexity to achieve a single unified pin scheme). It is worth noting that pin unification only makes sense if pins represent the same or compatible signals across different PR personas. If timing or resource constraints are strict, the algorithm may take more iterations or use a more sophisticated cost function to find a feasible solution. Balancing proximity to original placements, resource usage, and timing constraints is inherently a multi-objective problem. Starting with centroids and refining via small, local adjustments often yields good results in complex designs.

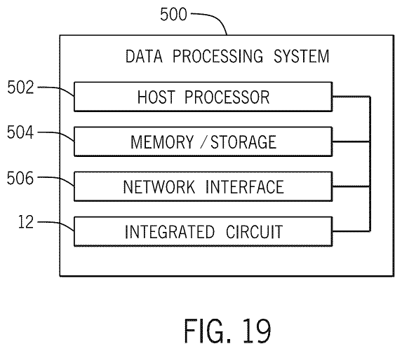

The integrated circuit device 12 discussed above may be a component included in a data processing system, such as a data processing system 500, shown in FIG. 19. The data processing system 500 may include the integrated circuit device 12 (e.g., a programmable logic device), a host processor 502, memory and/or storage circuitry 504, and a network interface 506. The data processing system 500 may include more or fewer components (e.g., electronic display, user interface structures, application specific integrated circuits (ASICs)). The host processor 502 may include any of the foregoing processors that may manage a data processing request for the data processing system 500 (e.g., to perform encryption, decryption, machine learning, video processing, voice recognition, image recognition, data compression, database search ranking, bioinformatics, network security pattern identification, spatial navigation, cryptocurrency operations, or the like). The memory and/or storage circuitry 504 may include random access memory (RAM), read-only memory (ROM), one or more hard drives, flash memory, or the like. The memory and/or storage circuitry 504 may hold data to be processed by the data processing system 500. In some cases, the memory and/or storage circuitry 504 may also store configuration programs (e.g., bitstreams) for programming the integrated circuit device 12. The network interface 506 may allow the data processing system 500 to communicate with other electronic devices. The data processing system 500 may include several different packages or may be contained within a single package on a single package substrate. For example, components of the data processing system 500 may be located on several different packages at one location (e.g., a data center) or multiple locations. For instance, components of the data processing system 500 may be located in separate geographic locations or areas, such as cities, states, or countries.

The data processing system 500 may be part of a data center that processes a variety of different requests. For instance, the data processing system 500 may receive a data processing request via the network interface 506 to perform encryption, decryption, machine learning, video processing, voice recognition, image recognition, data compression, database search ranking, bioinformatics, network security pattern identification, spatial navigation, digital signal processing, or other specialized tasks.

The techniques and methods described herein may be applied with other types of integrated circuit systems. To provide only a few examples, these may be used with central processing units (CPUs), graphics cards, hard drives, or other components.

While the embodiments set forth in the present disclosure may be susceptible to various modifications and alternative forms, specific embodiments have been shown by way of example in the drawings and have been described in detail herein. However, the disclosure is not intended to be limited to the particular forms disclosed. The disclosure is to cover all modifications, equivalents, and alternatives falling within the spirit and scope of the disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

### EXAMPLE EMBODIMENTS

### Example Embodiment 1

A system comprising:
a programmable logic device configurable to be programmed with a plurality of partial reconfiguration personas in a partial reconfiguration region of the programmable logic device; and
a data processing system to determine a boundary of the partial reconfiguration region based on a superimposition of the plurality of partial reconfiguration personas.

### Example Embodiment 2

The system of example embodiment 1, wherein the data processing system is to determine the boundary of the partial reconfiguration region using operations comprising:
separately compiling the plurality of partial reconfiguration personas;
superimposing the compilations; and
selecting, as the boundary of the partial reconfiguration, a bounding box that comprises all hardened components of all of the compilations.

### Example Embodiment 3

The system of example embodiment 2, wherein the data processing system is to determine the boundary of the partial reconfiguration region using operations comprising:
identifying hotspot areas for each of the compilations having a density greater than a density threshold;
wherein the bounding box is selected to at least partially encompass all of the hotspots.

### Example Embodiment 4

The system of example embodiment 2, wherein the hardened components comprise an adaptive logic module, a digital signal processor, or embedded memory, or any combination thereof.

### Example Embodiment 5

The system of example embodiment 1, wherein the data processing system is to determine the boundary of the partial reconfiguration region using a convex hull-based algorithm.

### Example Embodiment 6

The system of example embodiment 5, wherein the data processing system is to determine the boundary of the partial reconfiguration region using the convex hull-based algorithm to select a rectilinear shape unifying regions of greatest density in the superimposition of the plurality of partial reconfiguration personas.

### Example Embodiment 7

The system of example embodiment 6, wherein the data processing system is to determine the boundary of the partial reconfiguration region using the convex hull-based algorithm to generate multiple sub-hulls and combine the sub-hulls to determine the boundary of the partial reconfiguration region.

### Example Embodiment 8

The system of example embodiment 1, wherein the data processing system is to use an iterative geometric overlay to determine the boundary of the partial reconfiguration region.

### Example Embodiment 9

The system of example embodiment 1, wherein the data processing system is to determine a unified boundary port to be shared by all of the compilations of the plurality of partial reconfiguration personas.

### Example Embodiment 10

The system of example embodiment 9, wherein the data processing system is to determine the unified boundary port using operations comprising:
separately compiling the plurality of partial reconfiguration personas to determine different respective boundary port locations in a resulting plurality of compilations;
superimposing the plurality of compilations; and
selecting a unified boundary port based on the superimposition of the plurality of compilations.

### Example Embodiment 11

The system of example embodiment 10, wherein the data processing system is to determine the unified boundary port using operations comprising:
creating a virtual driver having a non-fixed placement based on the superimposition of the plurality of compilations; and
selecting a placement of the unified boundary port based on the placement of the virtual driver.

### Example Embodiment 12

The system of example embodiment 10, wherein the data processing system is to determine the unified boundary port using operations comprising:
creating a virtual multiplexer having a non-fixed placement based on the superimposition of the plurality of compilations; and
selecting a placement of the common input boundary port based on the placement of the virtual multiplexer.

### Example Embodiment 13

One or more tangible, non-transitory, computer-readable media comprising instructions that, when executed by a data processing system, cause the data processing system to carry out operations comprising:
determining a boundary of a partial reconfiguration region for a plurality of partial reconfiguration personas that are to be programmed into a field programmable gate array;
determining a unified boundary port into or out of the boundary of the partial reconfiguration region; and
generating a system design comprising compilations of the plurality of partial reconfiguration personas in the partial reconfiguration region using the unified boundary port.

### Example Embodiment 14

The one or more tangible, non-transitory, computer-readable media, wherein determining the boundary of the partial reconfiguration region comprises:
compiling the plurality of partial reconfiguration personas separately;
determining locations of one or more hotspots within each compilation of the plurality of partial reconfiguration personas corresponding to a density greater than a threshold; and
selecting a rectilinear shape as the boundary of the partial reconfiguration region based on the locations of the one or more hotspots within each compilation.

### Example Embodiment 15

The one or more tangible, non-transitory, computer-readable media, wherein selecting the rectilinear shape as the boundary of the partial reconfiguration region comprises applying a convex hull-based algorithm that at least partially encompasses the locations of the one or more hotspots within each compilation and locations of any hardened circuits used by any compilation.

### Example Embodiment 16

The one or more tangible, non-transitory, computer-readable media, wherein determining the unified boundary port into or out of the boundary of the partial reconfiguration region comprises determining a common input boundary port based on operations comprising:
compiling the plurality of partial reconfiguration personas separately;
determining locations of initial input boundary ports for each compilation of the plurality of partial reconfiguration personas;
determining locations of loads driven by the initial input boundary ports of each compilation of the plurality of partial reconfiguration personas;
creating one or more unified virtual drivers to drive the loads;
determining a placement for the unified virtual driver; and
determining a placement of the common input boundary port based on the placement of the unified virtual driver.

### Example Embodiment 17

The one or more tangible, non-transitory, computer-readable media, wherein determining the unified boundary port into or out of the boundary of the partial reconfiguration region comprises determining a common output boundary port based on operations comprising:
compiling the plurality of partial reconfiguration personas separately;
determining locations of initial output boundary ports for each compilation of the plurality of partial reconfiguration personas;
determining locations of drivers by the initial input boundary ports of each compilation of the plurality of partial reconfiguration personas;
creating one or more unified virtual multiplexers to receive signals from the drivers;
determining a placement for the unified virtual multiplexer; and
determining a placement of the common output boundary port based on the placement of the unified virtual multiplexer.

### Example Embodiment 18

A method comprising:
using a system design tool or a programmable logic device compiler to determine a boundary of a partial reconfiguration region for a plurality of partial reconfiguration personas that are to be programmed into the programmable logic device;
using the system design tool or the programmable logic device compiler to determine a unified boundary port into or out of the boundary of the partial reconfiguration region; and
using the system design tool or the programmable logic device compiler to generate a system design comprising the plurality of partial reconfiguration personas in the partial reconfiguration region using the unified boundary port.

### Example Embodiment 19

The method of example embodiment 18, wherein the system design tool or the programmable logic device is used to determine the boundary of the partial reconfiguration region using a convex hull-based algorithm to select a rectilinear shape unifying regions of greatest density of respective compilations of each of the plurality of partial reconfiguration personas.

### Example Embodiment 20

The method of example embodiment 18, wherein the system design tool or the programmable logic device is used to determine the unified boundary port into or out of the boundary of the partial reconfiguration region based on a superimposition of multiple compilations of the plurality of partial reconfiguration personas.

What is claimed is:

1. A system comprising:
a programmable logic device configurable to be programmed with a plurality of partial reconfiguration personas in a partial reconfiguration region of the programmable logic device; and
a data processing system to determine a boundary of the partial reconfiguration region based on a superimposition of the plurality of partial reconfiguration personas.

2. The system of claim 1, wherein the data processing system is to determine the boundary of the partial reconfiguration region using operations comprising:
separately compiling the plurality of partial reconfiguration personas;
superimposing the compilations; and
selecting, as the boundary of the partial reconfiguration, a bounding box that comprises all hardened components of all of the compilations.

3. The system of claim 2, wherein the data processing system is to determine the boundary of the partial reconfiguration region using operations comprising:
identifying hotspot areas for each of the compilations having a density greater than a density threshold;
wherein the bounding box is selected to at least partially encompass all of the hotspots.

4. The system of claim 2, wherein the hardened components comprise an adaptive logic module, a digital signal processor, or embedded memory, or any combination thereof.

5. The system of claim 1, wherein the data processing system is to determine the boundary of the partial reconfiguration region using a convex hull-based algorithm.

6. The system of claim 5, wherein the data processing system is to determine the boundary of the partial reconfiguration region using the convex hull-based algorithm to select a rectilinear shape unifying regions of greatest density in the superimposition of the plurality of partial reconfiguration personas.

7. The system of claim 6, wherein the data processing system is to determine the boundary of the partial reconfiguration region using the convex hull-based algorithm to generate multiple sub-hulls and combine the sub-hulls to determine the boundary of the partial reconfiguration region.

8. The system of claim 1, wherein the data processing system is to use an iterative geometric overlay to determine the boundary of the partial reconfiguration region.

9. The system of claim 1, wherein the data processing system is to determine a unified boundary port to be shared by all of the compilations of the plurality of partial reconfiguration personas.

10. The system of claim 9, wherein the data processing system is to determine the unified boundary port using operations comprising:
separately compiling the plurality of partial reconfiguration personas to determine different respective boundary port locations in a resulting plurality of compilations;
superimposing the plurality of compilations; and
selecting a unified boundary port based on the superimposition of the plurality of compilations.

11. The system of claim 10, wherein the data processing system is to determine the unified boundary port using operations comprising:
creating a virtual driver having a non-fixed placement based on the superimposition of the plurality of compilations; and
selecting a placement of the unified boundary port based on the placement of the virtual driver.

12. The system of claim 10, wherein the data processing system is to determine the unified boundary port using operations comprising:
creating a virtual multiplexer having a non-fixed placement based on the superimposition of the plurality of compilations; and
selecting a placement of the common input boundary port based on the placement of the virtual multiplexer.

13. One or more tangible, non-transitory, computer-readable media comprising instructions that, when executed by a data processing system, cause the data processing system to carry out operations comprising:
determining a boundary of a partial reconfiguration region for a plurality of partial reconfiguration personas that are to be programmed into a field programmable gate array;
determining a unified boundary port into or out of the boundary of the partial reconfiguration region; and
generating a system design comprising compilations of the plurality of partial reconfiguration personas in the partial reconfiguration region using the unified boundary port.

14. The one or more tangible, non-transitory, computer-readable media of claim 13, wherein determining the boundary of the partial reconfiguration region comprises:
compiling the plurality of partial reconfiguration personas separately;
determining locations of one or more hotspots within each compilation of the plurality of partial reconfiguration personas corresponding to a density greater than a threshold; and
selecting a rectilinear shape as the boundary of the partial reconfiguration region based on the locations of the one or more hotspots within each compilation.

15. The one or more tangible, non-transitory, computer-readable media of claim 14, wherein selecting the rectilinear shape as the boundary of the partial reconfiguration region comprises applying a convex hull-based algorithm that at least partially encompasses the locations of the one or more hotspots within each compilation and locations of any hardened circuits used by any compilation.

16. The one or more tangible, non-transitory, computer-readable media of claim 13, wherein determining the unified boundary port into or out of the boundary of the partial reconfiguration region comprises determining a common input boundary port based on operations comprising:
compiling the plurality of partial reconfiguration personas separately;
determining locations of initial input boundary ports for each compilation of the plurality of partial reconfiguration personas;
determining locations of loads driven by the initial input boundary ports of each compilation of the plurality of partial reconfiguration personas;
creating one or more unified virtual drivers to drive the loads;
determining a placement for the one or more unified virtual drivers; and
determining a placement of the common input boundary port based on the placement of the one or more unified virtual driver.

17. The one or more tangible, non-transitory, computer-readable media of claim 13, wherein determining the unified boundary port into or out of the boundary of the partial reconfiguration region comprises determining a common output boundary port based on operations comprising:
compiling the plurality of partial reconfiguration personas separately;
determining locations of initial output boundary ports for each compilation of the plurality of partial reconfiguration personas;
determining locations of drivers by the initial output boundary ports of each compilation of the plurality of partial reconfiguration personas;
creating one or more unified virtual multiplexers to receive signals from the drivers;
determining a placement for the one or more unified virtual multiplexers; and
determining a placement of the common output boundary port based on the placement of the one or more unified virtual multiplexers.

18. A method comprising:
using a system design tool or a programmable logic device compiler to determine a boundary of a partial reconfiguration region for a plurality of partial reconfiguration personas that are to be programmed into a programmable logic device;
using the system design tool or the programmable logic device compiler to determine a unified boundary port into or out of the boundary of the partial reconfiguration region; and
using the system design tool or the programmable logic device compiler to generate a system design comprising the plurality of partial reconfiguration personas in the partial reconfiguration region using the unified boundary port.

19. The method of claim 18, wherein the system design tool or the programmable logic device compiler is used to determine the boundary of the partial reconfiguration region using a convex hull-based algorithm to select a rectilinear shape unifying regions of greatest density of respective compilations of each of the plurality of partial reconfiguration personas.

20. The method of claim 18, wherein the system design tool or the programmable logic device compiler is used to determine the unified boundary port into or out of the boundary of the partial reconfiguration region based on a superimposition of multiple compilations of the plurality of partial reconfiguration personas.
